(19) United States
(12) Patent Application Publication
(10) Pub. No.: US 2006/0127821 A1
(43) Pub. Date: Jun. 15, 2006

(54) Method of forming a photoresist pattern

(75) Inventor: Kouji Yagi, Ibi-gun (JP)

Correspondence Address: OLIFF & BERRIDGE, PLC, P.O. BOX 19928, ALEXANDRIA, VA, 22320, US

(73) Assignee: SANYO ELECTRIC CO., LTD., Moriguchi-shi (JP)

(21) Appl. No.: 11/295,489

(22) Filed: Dec. 7, 2005

(30) Foreign Application Priority Data
Dec. 9, 2004 (JP) 2004-356324

(51) Int. Cl. G03F 7/00

(52) U.S. Cl. 430/322

(57) ABSTRACT

A method is provided that, when forming color filters of color photoresist for a solid-state imaging device, pigments are prevented from sublimating out of the photoresist during exposing light thereto to attach to the inside of a photolithography machine. Color photoresist is first applied onto a semiconductor substrate formed with a basic structure of a CCD image sensor, to form a photoresist film. A sublimation preventive film is further formed on the photoresist layer. The sublimation preventive film is selected for its material and thickness to have a transmissivity to light of from an exposure-light source and a function for preventing the pigment, etc. contained in the photoresist film from sublimating to the outside. The semiconductor substrate, formed with the sublimation preventive film, is rested in a photolithography machine, to expose the photoresist film to light by illuminating a ultraviolet ray through a photo-mask. In a photoresist film development made after the exposure to light, the sublimation preventive film is removed.

### BACKGROUND OF THE INVENTION

1. Field of the Invention

The present invention relates to a method to form a photoresist pattern.

2. Description of Related Art

In a semiconductor device manufacturing process, a circuit pattern is formed on a semiconductor substrate by use of a photolithography technique. In photolithography, photoresist is applied onto the semiconductor substrate and exposed to light through use of a photo-mask. Depending upon the presence or absence of illumination of light in an exposure-to-light step, the photoresist is selectively changed insoluble for the developing solution. The photoresist in a part not changed insoluble is removed away by development, to transfer a pattern of the photo-mask onto the semiconductor substrate. For example, by using the patterned photoresist, etching or ion-implant can be selectively done onto the semiconductor substrate at between the area with the photoresist left and the area with the photoresist removed away.

Meanwhile, photoresist is utilized as a material of a color filter to be mounted on an,image pickup, etc. for a solid-state imaging device. For example, photoresist transmissive to visible light is mixed with a pigment or a dye and adjusted in transmission color. By applying and patterning it over the image pickup, color filters can be formed correspondingly in position to light-receiving pixels (optical elements). By repeating the application and patterning of color photoresist on each of a plurality of transmission colors, it is possible to form a filter array arranged with a plurality of colors periodically.

FIG. 1 is a flowchart outlining the process to form a photoresist pattern over a semiconductor substrate. FIGS. 2A-2C are typical views explaining the process to form a photoresist pattern wherein FIG. 2A shows a step of applying photoresist, FIG. 2B a step of exposure to light, and FIG. 2C a state in a development step as viewed laterally. Photoresist is formed of an organic solvent or the like in a liquid state. Such liquid photoresist is applied onto a semiconductor substrate 20 by a spin coat technique or the like (S2, FIG. 2A). The semiconductor substrate 20a, on which a photoresist film 22 is formed over the surface, is heated up in pre-baking, thereby volatizing the organic solvent contained in the photoresist film 22 (S4). Then, the semiconductor substrate 20a is placed in a photolithography machine where it is exposed to light (S6). In the exposure to light, a photo-mask 24 is arranged in the above of the semiconductor substrate 20a. Through the photo-mask 24, ultraviolet rays of light are radiated to the semiconductor substrate 20a (FIG. 2B). This prints the pattern of the photo-mask 24 onto the photoresist film 22. After exposure to light, development is performed to selectively remove the photoresist layer 22. For example, where negative photoresist is used, the photoresist film 22a in an area illuminated with light 26 is left on the semiconductor substrate 20 by development (S8, FIG. 2C). The development is performed by utilization of a difference in solubility for developer between the area illuminated with light from a light source and the area not illuminated therewith. After the development, post-baking is performed to burn the photoresist patterned through the exposure step S6 and development step S8 (S10).

When the photoresist is exposed to light within the photolithography machine, a sublimation ingredient is possibly released out of the photoresist at a certain optical energy of illumination. For example, from a color photoresist forming color filters for a solid-state imaging device, the pigment or dye contained possibly sublimates. The sublimated ingredient is put in the photolithography machine, causing contamination on the machine or the photo-mask. This results in a problem of deteriorated performance of exposure to light and quality lowering in the semiconductor device manufactured by use of the photolithography machine.

### SUMMARY OF THE INVENTION

It is an object of the present invention to provide a method of forming a photoresist pattern while preventing the contamination in a photolithography machine due to a sublimation substance upon exposure to light.

A method of patterning a photoresist according to the invention comprises: a step of forming, on a surface of the photoresist film, a sublimation preventive film having a light-transmissivity and preventing a sublimation ingredient contained in the photoresist film from being released; and a step of exposing the photoresist film to light at within a photolithography machine after the sublimation preventive film forming step.

### BRIEF DESCRIPTION OF THE DRAWINGS

FIG. 1 is a flowchart outlining an existing process to form a photoresist pattern over a semiconductor substrate;

FIG. 2A is a typical view showing a state that resist is applied onto the substrate, in the existing method to form a photoresist pattern;

FIG. 2B is a typical view explaining a light-exposure step in the existing method to form a photoresist pattern;

FIG. 2C is a typical view explaining a developing step in the existing method to form a photoresist pattern;

FIG. 3 is a flowchart outlining a process to form a color filter pattern over a surface of an image pickup for a CCD image sensor;

FIG. 4A is a typical view showing a state that resist is applied onto the substrate, in the method of forming a photoresist pattern according to the invention;

FIG. 4B is a typical view explaining a state of after forming a sublimation preventive film, in the method of forming a photoresist pattern according to the invention;

FIG. 4C is a typical view explaining a light-exposure step, in the method of forming a photoresist pattern according to the invention; and

FIG. 4D is a typical view explaining a developing step, in the method of forming a photoresist pattern according to the invention.

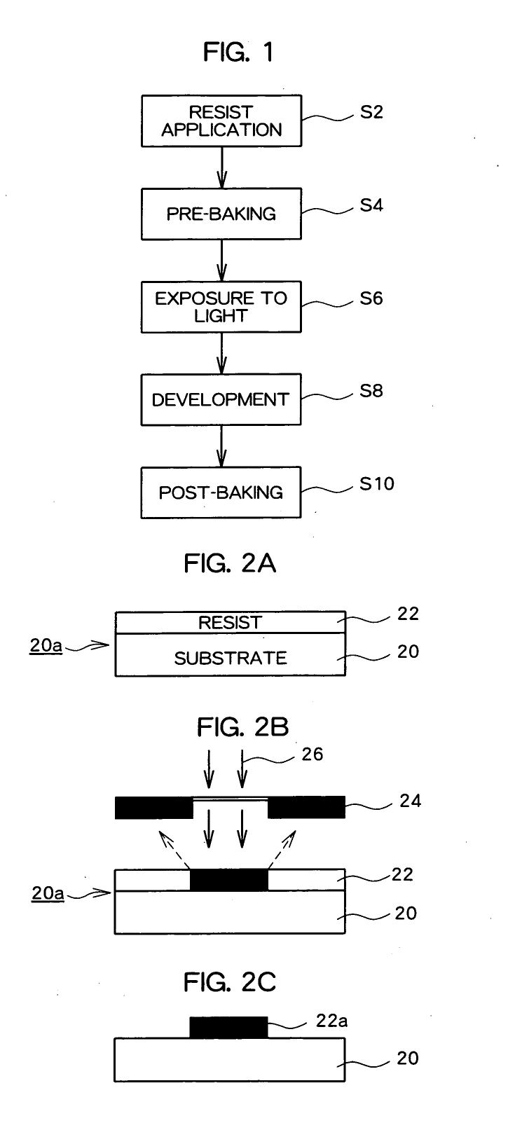

### DESCRIPTION OF THE PREFERRED EMBODIMENT

Description is now made on a color filter manufacturing method in an embodiment of the present invention, based on the drawings.

The present color filters are arranged, for example, on an image pickup of a CCD image sensor. For a CCD image sensor, its light-receiving region, CCD shift register channel, etc. are formed on a semiconductor substrate by the processing including ion implant and thermal oxidation. Furthermore, a polysilicon film, etc. are formed on the semiconductor substrate, which is patterned to form transfer electrodes for CCD shift registers. This is formed thereon with a passivation film, an interconnection such as of aluminum, a planarizing film and the like. Color filters are thereafter formed over the light-receiving elements.

For example, correspondingly to the array of light-receiving elements arranged in a matrix form in the image pickup, a filter array is formed with a plurality of light-transmissive color filters in a mosaic form. In this connection, the colors constituting a filter array may be a set of primary colors including red, green and blue or a set of complementary colors including cyan, magenta and yellow. The color filters are formed with photoresist that is colored by mixing therein a pigment or dye (color photoresist). The color photoresist is applied and patterned on the image pickup into an arrangement over objective light-receiving elements. By repeating the application and patterning of color photoresist on each of the plurality of light-transmissive colors, a filter array is formed with a plurality of colors arranged periodically.

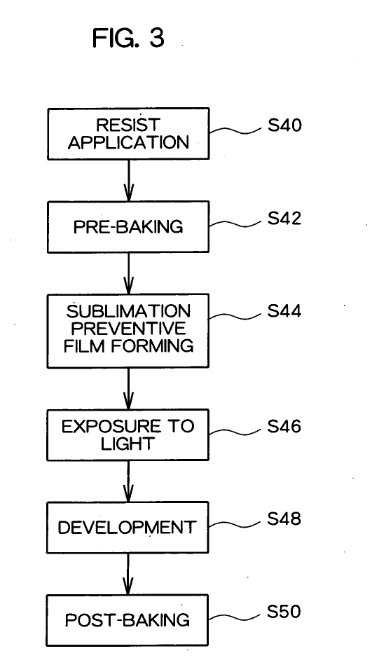

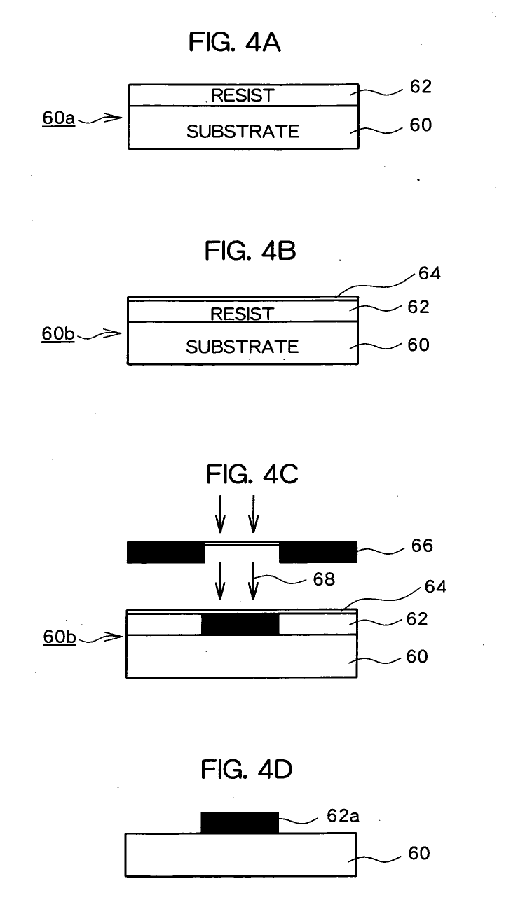

FIG. 3 is a flowchart outlining the process to form a color filter pattern over an image pickup, for a CCD image sensor, whose structure up to a planarization film, etc has been formed. FIGS. 4A-4D are typical views explaining the process to form a photoresist pattern structuring a color filter, showing the state of processing as viewed laterally.

Photoresist is a liquid of an organic solvent or the like. Photoresist in a liquid form is applied onto a semiconductor substrate 60, on which a CCD image sensor is to be formed, by spin coating, for example (S40). FIG. 4A shows a semiconductor substrate 60a after the application of photoresist, wherein a photoresist film 62 is formed over a surface of the semiconductor substrate 60.

The semiconductor substrate 60a is subjected to pre-baking (S42). In the pre-baking step (S42), the semiconductor substrate 60a is heated by a method, e.g. infrared heating or hot plate. Due to this, the organic solvent in the photoresist layer 62 is caused to volatalize.

After pre-bake step S42, a sublimation-preventive-film forming step S44 is carried out. By this processing S44, a sublimation-preventive film 64 is formed on a surface of the photoresist layer 62 of the semiconductor substrate 60a. The sublimation-preventive film 64 is formed to satisfy such a condition that allows the light of a radiation light source to transmit during exposure-to-light to be conducted later and prevents the pigment, etc. contained in the photoresist film 62 from sublimating during exposure to light. For example, the material is selected and the thickness of application is set up, in a manner satisfying the condition. The sublimation-preventive film 64 can use a material for anti-reflective coating that is to suppress the multiple reflections within the photoresist during exposure to light. With this material, a film is formed on the photoresist film 62 by the method of application, CVD or the like. For example, there is AZ Aquator (registered trademark) commercially marketed by AZ Electronics Materials, as a material for anti-reflective coating for use in forming a sublimation-preventive film 64. FIG. 4B shows a semiconductor substrate 60b on which a sublimation-preventive film 64 has been formed.

After forming a sublimation-preventive film 64, the photoresist film 62 is exposed to light at within a photolithography machine (S46). In the exposure-to-light step S46, a photo-mask 66 is arranged above the semiconductor substrate 60b. After aligning the semiconductor substrate 60b with the photo-mask 66, an ultraviolet ray of light 68 is applied to the semiconductor substrate 60b through the photo-mask 66. FIG. 4C shows a manner of exposure to light. This prints the pattern of the photo-mask 66 onto the photoresist 62. Because the photoresist film 62 is covered with the sublimation-preventing film 64 in the exposure-to-light step S46, sublimation of pigment and the like from the photoresist film 62 is prevented, which in turn prevents contamination at the interior of the printer.

After the exposure-to-light step S46, the semiconductor substrate 60b is taken out of the photolithography machine and developed in a developing apparatus (S48). Development is conducted by use of an exclusive developing solution suited for the photoresist type. In the photoresist film 62, a difference in solubility for developing solution at between the area exposed to light and the area unexposed to light is caused. By the utilization of the difference, the photoresist film 62 is selectively removed. For example, where negative photoresist is used, the photoresist film 62a in a portion applied with light 68 is left on the semiconductor substrate 60.

In this development step S48, the sublimation-preventive film 64 is removed together. FIG. 4D shows a state after development has been done. Incidentally, where the sublimation-preventive film 64 is formed of a material insoluble or non-strippable in developing the underlying photoresist film 62, the sublimation-preventive film 64 is separately removed prior to a development step S48.

After the development, post-bake is performed to burn the photoresist film 62a patterned in the exposure-to-light step S46 and development step S48 (S50).

By the above process, color filters are patterned on the semiconductor substrate 60 correspondingly to one transmissive color. By repeating the process on each of the transmission colors, a color-filter array is to be formed on image pickup for a CCD image sensor.

The method of patterning a photoresist film applied over a substrate, comprises: a step of forming, on a surface of the photoresist film, a sublimation preventive film having a light-transmissivity and preventing a sublimation ingredient contained in the photoresist film from being released; and a step of exposing the photoresist film to light in a photolithography machine after the sublimation preventive film forming step.

Particularly, as in the embodiment, a photoresist film can be formed by color photoresist containing a coloring agent, on a substrate previously formed with an optical element. With the photoresist film, a light-transmissive filter can be formed which is provided on a surface of the optical element and has a color based on the coloring agent. Although the optical element, in the embodiment, was a light-receiving element for a CCD image sensor, it may be another type of optical element. For example, the optical element may be a light-emitting element like a display device pixel.

According to the invention, because a sublimation preventive film is formed on a surface of the photoresist film prior to exposure to light, a sublimation substance is prevented from being released out of the photoresist film to the interior of the photolithography machine during exposure to light.

What is claimed is:

1. A method of patterning a photoresist film applied on a substrate, the method comprising:
a step of forming, on a surface of the photoresist film, a sublimation preventive film having a light-transmissivity and preventing a sublimation ingredient contained in the photoresist film from being released; and
a step of exposing the photoresist film to light at within a photolithography machine after the step of forming the sublimation preventive film.

2. The method of patterning a photoresist film of claim 1, wherein the substrate is previously formed with an optical element, the photoresist film being of color photoresist.

3. The method of patterning a photoresist film of claim 2, wherein the optical element is a light-receiving element for a solid-state imaging device.

4. The method of patterning a photoresist film of claim 1, further comprising a step of developing the photoresist film after the step of exposing the photoresist film, the sublimation preventive film is of a material to be removed in the developing step.

5. The method of patterning a photoresist film of claim 1, wherein the sublimation preventive film is formed of a material for anti-reflection coating preventing multi-reflection, in the light-exposure step.
